(19) United States
(12) Patent Application Publication
(10) Pub. No.: US 2009/0317980 A1
(43) Pub. Date: Dec. 24, 2009

(54) FILTER, SUBSTRATE TREATMENT APPARATUS AND SUBSTRATE TREATMENT METHOD

(75) Inventors: Hiroyasu Iimori, Kanagawa (JP); Hisashi Okuchi, Oita (JP); Hiroshi Tomita, Kanagawa (JP); Yoshihiro Ogawa, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Kabushiki Kaisha Toshiba

(21) Appl. No.: 12/548,814

(22) Filed: Aug. 27, 2009

Related U.S. Application Data
(62) Division of application No. 11/076,231, filed on Mar. 10, 2005.

(30) Foreign Application Priority Data
Mar. 15, 2004 (JP) 2004-73204

(51) Int. Cl. H01L 21/306

(52) U.S. Cl. 438/745; 257/E21.219

(57) ABSTRACT

A filter connectable to an external circulating system, the circulating system being included by a substrate treatment apparatus which etches a substrate with an H₃PO₄ solution, the filter includes:

a chemical feeding port which permits feed of H₃PO₄ solution containing particles deposited due to etching of a substrate;

an H₂O adding port which permits the addition of H₂O;

a filter film which removes the particles from the H₃PO₄ solution whose heat distribution is made ununiform by the addition of H₂O; and

a protection member which is disposed between the H₂O adding port and the filter film and which protects the filter film from bumping of the H₃PO₄ solution that is causable by the addition of H₂O.

### CROSS REFERENCE TO RELATED APPLICATION

This application claims benefit of priority under 35USC §119 to Japanese Patent Application No. 2004-73204, filed on Mar. 15, 2004, the contents of which are incorporated by reference herein.

### BACKGROUND OF THE INVENTION

1. Field of the Invention

The present invention relates to a filter, a substrate treatment apparatus and a substrate treatment method, and is intended for, for example, etching of a substrate to form a micropattern thereon.

2. Related Background Art

In etching a SiN film of a semiconductor substrate, it has been known that repetitive use of the same chemical solution would increase silica dust on a wafer after treatment with increase of the number of treatment batches. Therefore, it is necessary to exchange a dirty H₃PO₄ solution to a fresh one or to replace a filter in which a certain amount of silica is deposited, when a predetermined number of treatment batches and a predetermined amount of dissolved silica have been exceeded.

Various attempts have heretofore been made to reduce the silica dust in the H₃PO₄ solution. There have been mainly three methods to reduce the dissolved silica. The first method is to separate silica dissolved into the H₃PO₄ solution in a heat exchange area and then remove it with a filter, as described in, for example, Japanese laid open (kokai) 2002-299313 and Japanese laid open (kokai) 09-219388 (1997). The second method is to add H₂O which extremely drops temperature and reduces solubility, thereby separating the silica dust onto the filter for removal. Further, the third method is to add HF to the H₃PO₄ solution so that dissolved silica will be a gas of Sif₄ to be removed from the solution, as described in, for example, Japanese laid open (kokai) 09-45660 (1997), 07-86260 (1995), 10-50682 (1998) and 08-83792 (1996).

However, the problem associated with the first and second methods is that because the temperature of the H₃PO₄ solution is extremely decreased, reheating needs to be performed by a heater which requires costs. The third method also has a problem that the solution has to be adequately heated to remove the added HF from the H₃PO₄ solution.

### BRIEF SUMMARY OF THE INVENTION

According to a first aspect of the present invention, there is provided a filter connectable to an external circulating system, the circulating system being included by a substrate treatment apparatus which etches a substrate with an H₃PO₄ solution, the filter comprising:

a chemical feeding port which permits feed of H₃PO₄ solution containing particles deposited due to etching of a substrate;

an H₂O adding port which permits the addition of H₂O;

a filter film which removes the particles from the H₃PO₄ solution whose heat distribution is made ununiform by the addition of H₂O; and

a protection member which is disposed between the H₂O adding port and the filter film and which protects the filter film from bumping of the H₃PO₄ solution that is causable by the addition of H₂O.

According to a second aspect of the present invention, there is provided a substrate treatment apparatus comprising:

a treatment tank which receives a substrate to etch the substrate with an H₃PO₄ solution;

a circulating system which takes in the H₃PO₄ solution containing particles deposited in the treatment tank and which removes the particles and returns the H₃PO₄ solution to the treatment tank;

a pump attached to the circulating system to circulate the H₃PO₄ solution in the circulating system;

a filter attached to the circulating system, the filter including a chemical feeding port which permits the feed of the H₃PO₄ solution containing particles deposited by the etching, and a filter film which removes the particles from the H₃PO₄ solution;

an H₂O adder attached on an upstream side of the filter film of the filter to add H₂O to the H₃PO₄ solution so that a concentration of the H₃PO₄ solution is maintained within an arbitrary range and to impart an ununiform temperature distribution to the H₃PO₄ solution; and

a heater attached to the circulating system to heat the H₃PO₄ solution so that the H₃PO₄ solution at the arbitrary temperature is supplied to the treatment tank.

According to a third aspect of the present invention, there is provided a substrate treatment method using a substrate treatment apparatus which comprises a treatment tank which etches with an H₃PO₄ solution a substrate to be treated; a circulating system which takes in the H₃PO₄ solution containing particles deposited by the H₃PO₄ solution in the treatment tank and which removes the particles and returns the H₃PO₄ solution to the treatment tank; a pump attached to the circulating system to circulate the H₃PO₄ solution in the circulating system; a filter which includes an attachment part to be attached to the circulating system and a filter film to remove the particles from the H₃PO₄ solution; and a heater attached to the circulating system to heat the H₃PO₄ solution so that the H₃PO₄ solution at an arbitrary temperature is supplied to the treatment tank, the treatment method comprising:

adding H₂O to the H₃PO₄ solution on an upstream side of the attachment part of the filter in the circulating system to maintain a concentration of the H₃PO₄ solution within an arbitrary range and to impart an ununiform concentration distribution to the H₃PO₄ solution.

### BRIEF DESCRIPTION OF THE DRAWINGS

In the accompanying drawings:

FIG. 1 is a block diagram showing a schematic configuration in a first embodiment of a substrate treatment apparatus according to the present invention;

FIG. 2 is a block diagram showing a schematic configuration in a second embodiment of the substrate treatment apparatus according to the present invention;

FIG. 3 is a block diagram showing essential parts of one embodiment of a filter according to the present invention; and

FIG. 4 is a block diagram showing a schematic configuration in a third embodiment of the substrate treatment apparatus according to the present invention.

### DETAILED DESCRIPTION OF THE INVENTION

### (1) First Embodiment

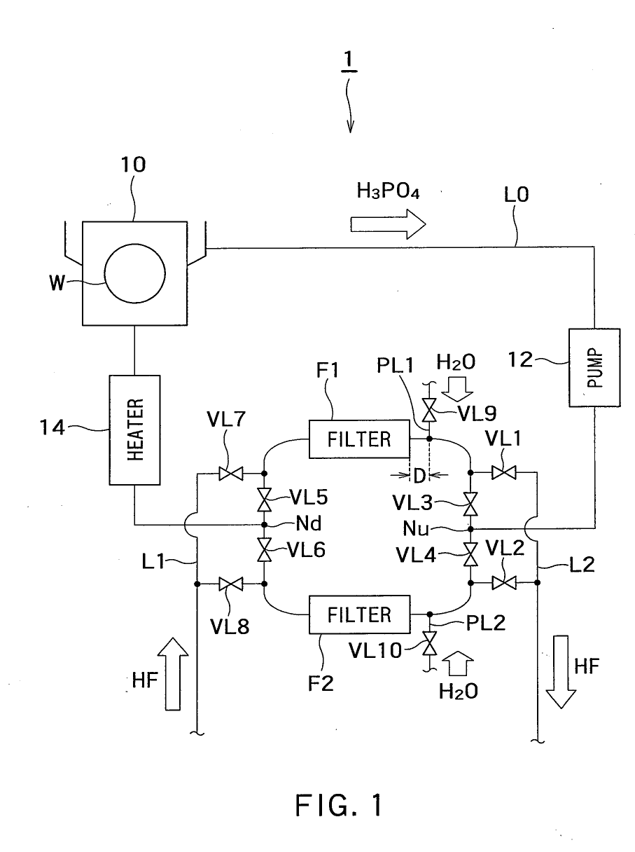

FIG. 1 is a block diagram showing a schematic configuration in a first embodiment of a substrate treatment apparatus according to the present invention. An etching apparatus 1 shown in FIG. 1 comprises a treatment tank 10, a circulation line L0, a pump 12, a heater 14, two filters F1, F2, cleaning lines L1, L2, H₂O replenishing lines PL1, PL2, and valves VL1 to VL10 to adjust the amount of replenishment chemical solution or H₂O.

The treatment tank 10 receives a semiconductor wafer W under manufacture to selectively remove by an H₃PO₄ solution all or part of a film formed in a surface layer or on a surface of the wafer W. Consequently, silica dust is dissolved into the H₃PO₄ solution, and the H₃PO₄ solution containing the silica dust is sucked by the pump 12 and then flows in the circulation line L0. The two filters F1, F2 are connected in parallel to each other and placed immediately before an upstream side of the heater 14, and remove the silica dust in the H₃PO₄ solution. The heater 14 heats the H₃PO₄ solution filtered by the filters F1, F2 and returns it to the treatment tank 10.

The valves VL3, VL4 are provided between a branch point Nu of the parallel connection on the upstream side of the filters F1, F2 and the respective filters, and they adjust an inflow amount of the H₃PO₄ solution into the respective filters. Similarly, the valves VL5, VL6 are provided between the branch point Nd of the parallel connection on the downstream side of the filters F1, F2 and the respective filters, and they adjust an outflow amount of the H₃PO₄ solution from the respective filters. Further, an HF solution feed line L1 for cleaning is connected via the valves VL7, VL8 to the circulation line L0 between the downstream valve VL5 and the filter F1 and to the circulation line L0 between the downstream valve VL6 and the filter F2, respectively. Moreover, an HF solution discharging line L2 is connected via the valves VL1, VL2 to the circulation line L0 between the upstream valve VL3 and the filter F1 and to the circulation line L0 between the upstream valve VL4 and the filter F2, respectively.

The H₂O replenishing lines PL1, PL2 are connected on the upstream side of the filters F1, F2 to the circulation line L0 immediately before the respective filters F1, F2 via the valves VL9, VL10, respectively, and replenish H₂O to the H₃PO₄ solution to maintain a concentration of the H₃PO₄ solution within an arbitrary range thereof.

Thus, according to the etching apparatus 1 in the present embodiment, since H₂O is added to the H₃PO₄ solution immediately before the respective filters, the temperature of the H₃PO₄ solution rapidly drops, the silica dust is deposited due to a decrease in solubility, and the filter which immediately follows removes the silica dust before different temperatures are uniformed. Thus, according to the etching apparatus 1 in the present embodiment, the H₃PO₄ solution can be cleaned by the filters with high efficiency while the concentration of the H₃PO₄ solution is held at an arbitrary value. Further, the filters F1, F2 connected in parallel are disposed immediately before the heater 14 at which the temperature of the H₃PO₄ solution is the lowest, and H₂O is added immediately before these filters, thereby creating a state in which particles are easily deposited. In this state where H₂O is locally added into the H₃PO₄ solution and the particles are deposited, the particles are removed from the H₃PO₄ solution, allowing elongation of the life of the chemical solution.

A distance D between each connection point of the H₂O replenishing line PL1, PL2 and the circulation line L0, and the filter F1, F2 is set within a range where the H₃PO₄ solution reaches a filter film in each filter until an ununiform temperature distribution caused in the H₃PO₄ solution when H₂O at room temperature is added to the H₃PO₄ solution at a high temperature (e.g., 160° C.) is uniformed.

As described above, since the etching apparatus 1 in the present embodiment comprises the two filters F1, F2 connected in parallel, the filters can be efficiently cleaned without stopping a cleaning treatment of the H₃PO₄ solution. A specific method thereof will be described below.

First, the valves VL3, VL5 are opened while the other valves remain closed so that the H₃PO₄ solution is passed through and filtered by the filter F1. When the time comes to clean the filter F1, the valves VL4, VL6 are opened and the valves VL3, VL5 are closed. In this way, the H₃PO₄ solution can be filtered by the filter F2 without stopping the cleaning treatment of the H₃PO₄ solution. Subsequently, the valves VL7, VL1 are opened to pass an HF solution from the valve VL7 side into the filter F1 through the HF solution feed line L1, and the HF solution is discharged from the valve VL1 side to the HF solution discharging line L2. When the cleaning of the filter F1 is completed, the valves VL7, VL1 are closed. Subsequently, when the time comes to clean the filter F2, the valves VL3, VL5 are opened, and then the valves VL4, VL6 are closed to switch the filter F2 to the filter F1. To clean the filter F2, the valves VL2, VL8 are opened so that the HF solution flows from the valve VL8 side. The above operation is repeated, so that the filters can be efficiently cleaned without stopping the cleaning treatment of the H₃PO₄ solution at the time when the filter is to be cleaned or replaced. Thus, semiconductor devices can be etched at high throughput. Moreover, as the filters can be frequently cleaned, the filters can be less frequently replaced.

### (2) Second Embodiment

In the first embodiment described above, the H₂O replenishing line PL1, PL2 are connected to the circulation line L0 in the vicinity of the respective filters on the upstream side of the respective filters. The present embodiment is described in such a manner that the H₂O replenishing lines PL1, PL2 are connected not to the circulation line L0 but directly to the respective filters.

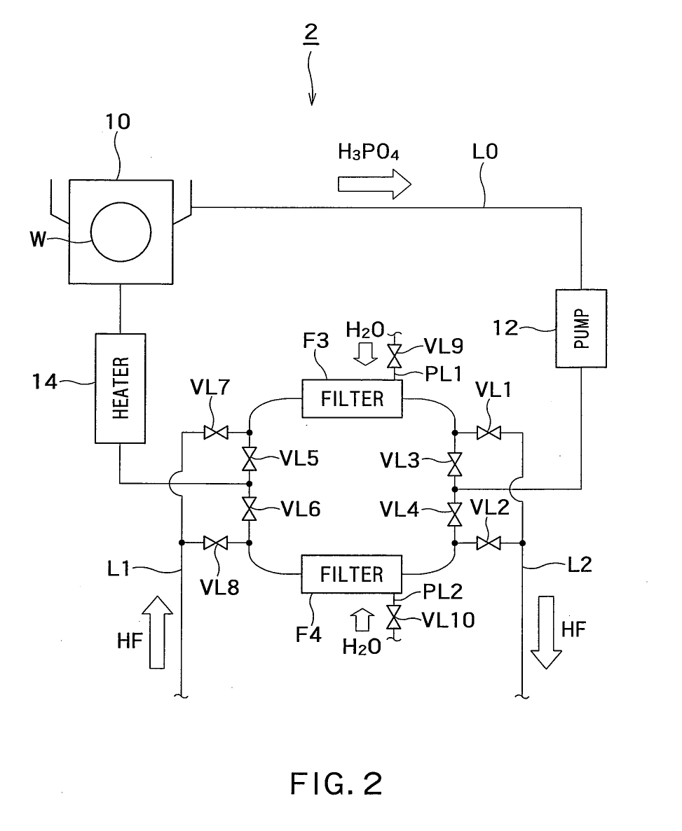

FIG. 2 is a block diagram showing a schematic configuration in a second embodiment of the substrate treatment apparatus according to the present invention. An etching apparatus 2 shown in FIG. 2 comprises filters F3, F4 as one embodiment of the filters according to the present invention, instead of the filters F1, F2 which the etching apparatus 1 shown in FIG. 1 comprises, and the H₂O replenishing line PL1, PL2 are directly connected to these filters F3, F4. The configuration in other parts of the etching apparatus 2 shown in FIG. 2 is substantially the same as that of the etching apparatus 1 shown in FIG. 1.

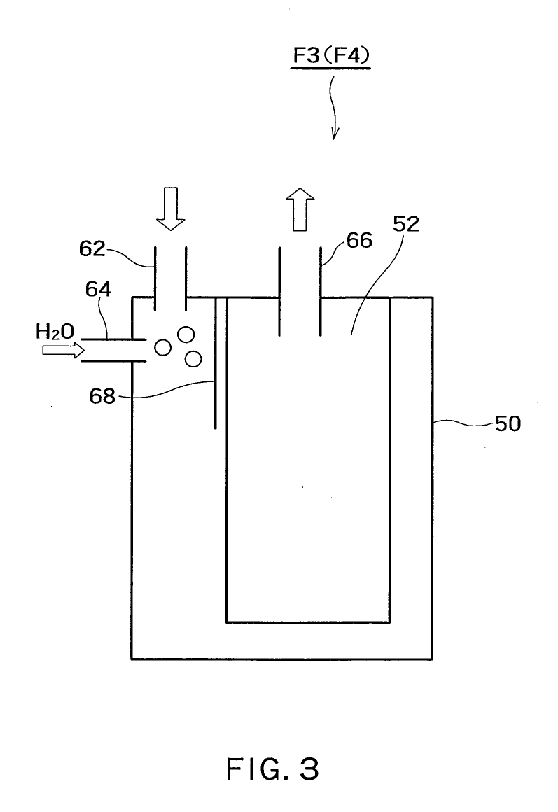

FIG. 3 is a block diagram showing essential parts of the filter F3 (F4) which the etching apparatus 2 in the present embodiment comprises. The filter F3 (F4) shown in FIG. 3 comprises a filter cover 50 provided with a chemical feeding port 62, a chemical discharging port 66 and an H₂O adding port 64; a filter film 52 contained in the filter cover 50; and a protective barrier 68. The H₂O adding port 64 is provided in the vicinity of the chemical feeding port 62, so that H₂O at room temperature is added to the H₃PO₄ solution at a high temperature, and immediately after this, the H₃PO₄ solution is introduced into the filter film 52 with the ununiform temperature distribution and efficiently filtered.

In the first embodiment described above, H₂O is added to the H₃PO₄ solution in the vicinity of the filters F1, F2, but in this case, the H₃PO₄ solution could cause bumping due to a temperature difference between the H₃PO₄ solution and H₂O, in which case the filter films of the filters F1, F2 might be damaged. As shown in FIG. 3, the filter F3 (F4) in the present embodiment comprises the protective barrier 68 provided between the filter film 52 and the filter cover 50, so that the filter film 52 can be protected from the damage when bumping occurs. This provides the filters with high filter efficiency and long life. The length of the protective barrier 68 may be such that the filter film 52 is not affected by the bumping.

### (3) Third Embodiment

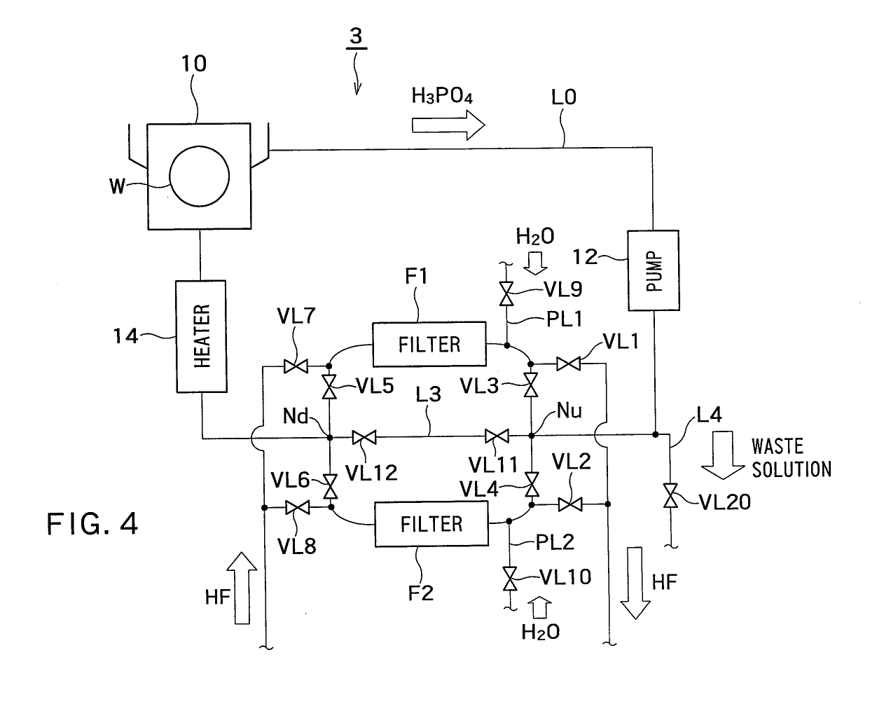

FIG. 4 is a block diagram showing a schematic configuration in a third embodiment of the substrate treatment apparatus according to the present invention. As apparent from contrast with FIG. 1, an etching apparatus 3 shown in FIG. 4 is characterized in that it further comprises a bypass line which is provided in a circulating system so as to couple the connection points Nu, Nd of the parallel connection of the filters F1, F2 and which does not have filters, and that a waste solution line L4 to exchange the H₃PO₄ solution is provided between the connection point Nu and the pump 12. Valves VL11, VL12 are respectively provided between a bypass line L3 and the connection points Nu, Nd, and these valves adjust the amount of H₃PO₄ solution passing through the bypass line L3. The configuration in other parts of the etching apparatus 3 shown in FIG. 4 is substantially the same as that of the etching apparatus 1 shown in FIG. 1. Therefore, in the filters F1, F2 connected in parallel, a method of switching the filters during the cleaning of the respective filters is the same as in the etching apparatus 1.

According to the etching apparatus 3 of the present embodiment, when the H₃PO₄ solution is exchanged, the bypass line without filters is used to enable smooth circulation of the exchanged H₃PO₄ solution. This will be described below.

For example, it is assumed that the exchange of the H₃PO₄ solution is needed when the valves VL3, VL5 are opened whereas the other valves are closed and the chemical H₃PO₄ solution is passing through the filter F1. In order to exchange the chemical solution, a valve VL20 is opened to start drawing off the H₃PO₄ solution from the circulation line L0 through the waste solution line L4.

With regard to the open/close state of the valves at this moment, the valves VL3, VL5 may be closed and the valves VL11, VL12 may be. opened immediately before the exchange of the chemical solution, or the valves VL3, VL5 may be closed and the valves VL11, VL12 may be opened when the chemical solution is completely drawn off. The fresh solution fed in the treatment tank 10 circulates sequentially from the treatment tank 10 to the pump 12 and the heater 14 without being subjected to the resistance of the filter F1 or F2. In this regard, the cleaning of the filter F1 which has been used until just before the exchange of the H₃PO₄ solution may be carried out in parallel with the circulation of the fresh H₃PO₄ solution. Specifically, the valves VL1, VL7 are opened so that the HF solution flows from the valve VL7 side by way of the HF solution feed line L1. When the cleaning is finished, the valves VL1, VL7 may be closed.

In this way, as the etching apparatus 3 of the present embodiment comprises the bypass line L3 on which filters are not placed, even the H₃PO₄ solution whose temperature is low and whose viscosity is high immediately after the exchange can be supplied to the treatment tank 10 after efficiently and uniformly heated without being subjected to the resistance of the filter.

1.-8. (canceled)

9. A substrate treatment method using a substrate treatment apparatus which comprises a treatment tank which etches with an H₃PO₄ solution a substrate to be treated; a circulating system which takes in the H₃PO₄ solution containing particles deposited by the H₃PO₄ solution in the treatment tank and which removes the particles and returns the H₃PO₄ solution to the treatment tank; a pump attached to the circulating system to circulate the H₃PO₄ solution in the circulating system; a filter which includes an attachment part to be attached to the circulating system and a filter film to remove the particles from the H₃PO₄ solution; and a heater attached to the circulating system to heat the H₃PO₄ solution so that the H₃PO₄ solution at an arbitrary temperature is supplied to the treatment tank, the treatment method comprising:
adding H₂O to the H₃PO₄ solution on an upstream side of the attachment part of the filter in the circulating system to maintain a concentration of the H₃PO₄ solution within an arbitrary range and to impart an ununiform concentration distribution to the H₃PO₄ solution.

10. The substrate treatment method according to claim 9, wherein
H₂O is added to the H₃PO₄ solution at a position apart from the filter by a distance in a range in which the H₃PO₄ solution is supplied to the filter before a heat distribution of the H₃PO₄ solution is uniformed.

11. The substrate treatment method according to claim 9, wherein
H₂O is added to the H₃PO₄ solution outside of the filter.

12. The substrate treatment method according to claim 9,
wherein H₂O is added to the H₃PO₄ solution between the attachment part and the filter film of the filter.

13. The substrate treatment method according to claim 9,
wherein the filter further includes a protection member which protects the filter film from bumping of the H₃PO₄ solution that is causable by the addition of H₂O.

14. The substrate treatment method according to claim 9, which further comprises feeding the filter with cleaning solution to clean the filter.

15. The substrate treatment method according to claim 9,
wherein the substrate treatment apparatus comprises a plurality of filters connected in parallel to the circulating system.

16. The substrate treatment method according to claim 9,
wherein the substrate treatment apparatus comprises a bypass line connected to the circulating system and
the method further comprises supplying fresh H₃PO₄ solution through the bypass line to bypass the filter in replacement of H₃PO₄ solution.
